(19) United States
(12) Patent Application Publication
(10) Pub. No.: US 2006/0172892 A1
(43) Pub. Date: Aug. 3, 2006

(54) Surface improvement method in fabricating high temperature superconductor devices

(76) Inventors: Zhenghe Han, Beijing (CN); Sansheng Wang, Beijing (CN); Kai Wu, Beijing (CN); Menglin Liu, Beijing (CN)

Correspondence Address: KODA & ANDROLIA, 2029 CENTURY PARK EAST, SUITE 1140, LOS ANGELES, CA, 90067, US

(21) Appl. No.: 10/541,296

(22) PCT Filed: Jul. 24, 2003
(86) PCT No.: PCT/CN03/00594

§ 371 Date: Jul. 6, 2005

(30) Foreign Application Priority Data
Dec. 30, 2002 (CN) 02159935.1

(51) Int. Cl. H01L 39/24

(52) U.S. Cl. 505/100

(57) ABSTRACT

A method of surface modification in fabricating High Temperature Superconducting devices, characterized in that bombarding the preformed material surface with a particle beam having energy, to improve the smoothness of the material surface and change the microstructure or internal defects of the processed material, wherein the energy of the particle beam is in the range of 5 ev to 50000 ev, and the incidence angle is in the range of 5 degree to 85 degree. In some cases, in order to achieve the desired superconductivity, the bombarded sample is annealed, and the annealing temperature is in the range of 100° C. to 1500° C. The present invention can improve the surface smoothness of the processed material, reduce the surface defect, change the microstructure of the material, and thereby improve the superconductivity of the whole device. The bombarded material comprises a substrate, a transition layer, superconducting layer or any combination of them during the process of the fabrication of the superconducting devices.

### FIELD OF THE INVENTION

This invention relates to a method for manufacturing a high temperature superconducting device, more particularly, a surface modification method of energy bearing particle beam by which device superconductivity can be improved.

### BACKGROUND OF THE INVENTION

Now the development of high temperature superconducting device has attracted worldwide attention. Today, the industrialization of bismuth (Bi) group wire characterized in copper oxide powder in tube (OPIT) has been realized successfully. The wire with kilometers long can be obtained from several corporations in the world. In this technology, the material is pressed into a shape first, then is sintered and grows at high temperature. However, the surface of the final product is rough, and may contain pores, gaps and cracks, thereby reducing its superconducting performance.

In the meanwhile, the study on YBCO (Y₁Ba₂Cu₃O₇) high temperature superconductor film with good high-field performance has a breakthrough also. The high temperature superconducting film conductor growing on the single crystal substrate with vacuum technique has realized some limited electronics application, such as manufacturing high temperature superconducting filter. However, the single crystal substrate is not suited for the large-scale application as conductor, such as power transmission, magnetic energy storage, motor and the like. Therefore, the metal substrate is usually adopted. Because metal substrate can not provide the same biaxial orientation requested for epitaxial growth of superconducting film as the single crystal substrate, before the epitaxial growth of superconducting thin film, one or more intermediate transition layers is pre-formed on the metal substrate so as to establish the biaxial texture to fit the epitaxial growth of superconducting film and avoid the atom diffusion from the metal substrate to the superconducting film, which may destroy the electrical performance of superconducting film. Thus, generally the high temperature superconducting film in the high temperature superconducting device has multi-layer structure including the substrate, the intermediate transition layers (barrier layers) and the high temperature superconducting film.

One of the main affecting factors on superconductivity of the high temperature superconducting film is the quality of the superconducting film itself, including surface smoothness, epitaxial orientation, defects distribution and property of grain boundary. Moreover, as the film thickness increases, the surface of superconducting film becomes rough and the orientation is changed, thereby the growth of the subsequent film or multi-layer film is affected. The next affecting factor is the quality of the substrate and the barrier layer(s). Because the texture of the superconducting film is typically formed through the “transfer” of the substrate and the barrier layer, the improvement of the smoothness and texture of the substrate and the barrier layer facilitates to improve the superconductivity of the whole high temperature superconducting film. Another possible solution is that the texture of epitaxial superconducting film is provided by the barrier layer, regardless of the substrate texture and the surface condition. Apparently, in this case, the texture and surface quality of the barrier layer become very important. Therefore, during the preparation process of high temperature superconducting device, the control of the smoothness and structure of material surface plays a key role in producing the high temperature superconducting device.

At present, there are many processes to prepare the YBCO high temperature superconducting coated conductor, which are mainly divided into two types. One type of process is vacuum process, including ion-beam assisted deposition (IBAD), rolling assisted biaxially textured substrates (RABiTS), modified bias sputtering (MBS), inclined substrate deposition (ISD), pulsed laser deposition (PLD), sputtering, electron beam evaporation and metalorganic chemical vapor deposition (MOCVD) and the like. Several approaches have been provided to promote biaxially textured grains growth on the substrate that can not provide epitaxial template. One approach is inclined substrate deposition (ISD) which can obtain the growth of buffer layer with the biaxial orientation through adjusting the tilt angle between the substrate and the axis of the vapor source, without consideration of the substrate texture. But in order to attain the desired degree of biaxial orientation, this approach is required to deposit a thick film (for YSZ, about 1 μm). Another approach for fabricating superconductor tapes on flexible metal tape is ion-beam assisted deposition (IBAD). The IBAD process utilizes an oblique ion beam to bombard the deposited film during the deposition of the film, thereby obtaining the barrier layer with biaxial orientation. The advantage of this process is that the required biaxial orientation barrier layer can be formed almost on any substrate. But just like ISD, to obtain the required degree of biaxial orientation, thick film depositing is needed. Since deposition rates of IBAD are very slow, this technology is not adapted to practical applications. Another approach is rolling assisted biaxially textured substrates (RABiTS), which adopts metal rolling and thermal annealing technology to induce biaxial orientation on the metal tape directly. But generally the higher temperature (for Ni, 900-1200° C.) and longer processing time (for Ni, up to 10 hours) are required in the process of heat treatment. Furthermore, after the heat treatment, the additional electrochemical polishing process is needed because the metal surface is rough. These make the practical application become difficult.

Generally speaking, the advantage of the vacuum process is that the formed material exhibits excellent smoothness and texture, the defects are few and the critical current density J_{c} is high. Its disadvantage is that the manufacturing cost is high and the production efficiency is low. Thus, it is difficult to realize large-scale application as conductor, such as power transmission, magnetic energy storage, motor and the like.

The other type is non-vacuum process. The non-vacuum process to prepare the high temperature superconducting film conductor typically includes sol-gel process, aerosol/spray pyrolysis process, metalorganic deposition (MOD) process, electrophoresis process, liquid phase epitaxial process and screen printing process, etc. Compared with the vacuum process with high manufacturing cost and low production efficiency, the non-vacuum process has advantages of easy operation, short production cycle and cheap cost, and fit for the large-scale industrialization.

Several non-vacuum processes are described briefly as below.

(1) Sol-gel process

U.S. Patent (U.S. Pat. No. 6,235,402) discloses a sol-gel technique, in which the solution dissolving the prefabricated powders forms a film through dip coating process, and then is dried and is subjected to heat treatment. Its representative process comprises following steps:

\textcircled{1} Preparation of sol: dissolving precursor materials into solution (typically, nitrate, alkoxide, acetate, etc.)

\textcircled{2} Preparation of gel: evaporating the solution to remove the most of solvent, then dissolving again to form gel;

\textcircled{3} Dip coating or spin coating;

\textcircled{4} Pyrolysis and oxygenation for forming the required film.

The Sol-gel technique has advantages of cheap cost, high efficiency, rapid speed, low impurity content, uniform components, low preparation temperature and simple preparation process, and fits for large scale production. However, the deposit occurs easily during the heat treatment of the gel, the surface of the film prepared is rough and contains defects, such as pores, cracks and second-phases. Presently,-the capability of carrying current of the prepared high temperature superconducting film with this process can not satisfy the requirements of industrial application yet.

(2) Aerosols/spray pyrolysis

U.S. patent (U.S. Pat. No. 6,261,704) discloses an aerosols/spray pyrolysis technique. The basic process thereof is to dissolve the cuprates (generally including nitrate, alkoxide, acetate, etc.) into nitric acid solution in proportion, and then to make it into aerosol and to spray the aerosol onto the substrate (Ni, Al, Cu, etc.) preheated to a certain temperature by a sprayer unit. The sample subject to spray is then put into the zone-melting furnace to conduct zone-melting treatment and is sintered at the predetermined atmosphere finally.

Because this technique needs a specific sprayer unit, its cost is higher than other non-vacuum processes. In addition, the surface of the prepared film is relatively rough and contains some defects. At present, the high temperature superconducting film prepared by this process is difficult to be put into practical use.

(3) Metalorganic deposition

Metalorganic deposition process (P. C. McIntyre, Journal of Applied Physics, 71 (4), 1868 (1992)) is a method for forming homogeneous film from liquid phase solution. The following is a general process flow: the acetate compounds are dissolved in the precursor stock solution according to the strict stoichiometric proportion. Next, the solution is dissolved in the organic solvent, and the resulting solution is deposited on the smooth surface of the substrate by dip coating or spin coating, and then through drying and oxygenation treatment at high temperature, the required material is available. Normally SrTiO3, LaAlO3 or sapphire single crystal is used for the substrate material in this process.

This process has the advantages of short deposition process and low cost. Moreover, in the process, the components of the final product can be controlled easily, the film can be formed on an irregular substrate, and the process is suitable for large scale production. However, in the MOD process, it is very difficult to form the thick film required by industry, also, the deposition is produced easily. Thus, the prepared film has usually rough surface and contains defects.

(4) Electrophoretic deposition process

Electrophoretic deposition process ( L. D. Woolf etc, Applied Physics Letter, 58 (5), 543(1991)) is an electrochemical method, which is used to deposit prefabricated powders suspending in the solution on the substrate surface through electric field. Its typical process flow comprises following steps: the prefabricated powders are dissolved into the acetone to form suspension; then the alumina plate coated with silver is used as cathode substrate and the stainless steel screen submerged into the suspension is used as anode; the additive is added into the suspension while predetermined electrode voltage is applied to coat the film.

This process is of the advantages of high rate of deposition and low cost. However, the prepared film has worse microscopic structure, rough surface, low tightness and some defects; also, its components are difficult to control. Since its critical current density is too low to satisfy the needs of industrial application.

(5) Liquid phase epitaxial process

U.S. patent (U.S. Pat. No. 6,008,162) discloses a liquid phase epitaxial process, in which the superconducting film is prepared from BaO—CuO molten oxides at high temperature by a top seed crystal molten growth method.

This method can form the film under ordinary pressure; and the film has accurate stoichiometry, fast growth rate and high crystallinity. The drawbacks of this process lie in that the prepared film has worse microscopic structure, rough surface, defects and large angle grain boundary. In addition, the requirement for the higher working temperature not only increases the cost but also easily leads to chemical reaction between the molten zone and the substrate material. As a result, the performance of the material is reduced.

(6) Screen printing process

Screen printing process (Qirui Zhang, “High Temperature Superconductivity”, Zhejiang University Press, 1992) includes the following steps: fully mixing the prefabricated powders with proper bond (such as polyvinyl alcohol) and adding the solvent to form diffluent slurry with certain flowability; passing it through mesh screen of special shape and brushing it on a predetermined area of the substrate (such as ZrO₂, Al₂O₃, MgO, etc.) to form a printed circuit; forming the required film finally after drying and sintering treatment.

This process has advantages of high efficiency and low cost. But the film prepared with this process has worse microscopic structure and rough surface as well as some defects and large angle grain boundary. At Present, the reached critical current density is too low and only 100-1000 A/cm² under the condition of zero-field of 77K.

It is noted that U.S. Patent Application Publication No. 2002/0073918 (Jun. 20, 2002) disclosed a process for obtaining or enhancing the biaxial texture of the substrate. The surface of preformed non-single-crystal material is bombarded with a particle beam. The biaxial texture is formed on the bombarded surface zone of the material (1-100 nm) which acts as a template of the subsequent epitaxial growth film. The energy range of the adopted particle beam is 10-20000 eV. The preliminary results show that, compared with the amorphous material YSZ which is not subject to the modification, the textured nucleating layer is obtained on the surface layer (1-2 nm) with Ar⁺ bombardment of 300 eV. Then the YBCO growth with good c-axis orientation is obtained on the modified YSZ surface.

### SUMMARY OF THE INVENTION

In view of the above problems, the invention provides a particle beam surface modification method in fabricating a high temperature superconducting device. This method adopts energy bearing particle beam to bombard the surface of the preformed material to decrease or eliminate irregular state and defect of the processed surface, increase surface smoothness and change the microstructure of processed material (such as texture or internal defect), thereby improving the superconductivity of the device.

The surface smoothness mentioned in the present invention includes two aspects of both macroscope and microscope, i.e. large area uniformity and microcosmic smoothness.

The material texture refers to such a condition that one axis is parallel with a normal (z-axis) of the plane defined by x-axis and y-axis, the other axis is parallel with an axial line in the plane defined by x-axis and y-axis, which form the so-called “biaxial texture”.

In the present invention, the bulk material structure formed after the particle beam bombardment refers to a structure designed for realizing the desired superconductivity. The modification layer of the actual material may be bulk, external or internal.

The internal defect formed after the particle beam bombardment refers to linear dislocation, point defects and the like which are introduced intentionally to improve superconducting performance, such as magnetic flux pinning performance.

The present invention provides a method for surface modification in manufacturing high temperature superconducting device, comprising the step of:

bombarding a surface of a preformed material with a particle beam having energy to increase the smoothness of the material surface and change the microstructure or internal defect of the processed material;

wherein the energy of the particle beam is in the range of 5-50000 eV, and the incidence angle of the particle beam is in the range of 5-85 degree.

In one embodiment, the material may be MgO, and the incidence angle of the particle beam may be in the range of 35-85 degree. The material may be CeO₂, and the incidence angle of the particle beam may be in the range of 45-85 degree. The material may be a cold rolled Ni substrate, and the incidence angle of the particle beam may be in the range of 10-80 degree. The material may be YBCO, and the incidence angle of the particle beam may be in the range of 5-85 degree. The material may be any one of following metal materials: Ni, NiO, Ni alloy, Cu, Cu alloy, Ag, Ag alloy, Fe, Fe alloy, Mg and Mg alloy, purities of the alloy materials may be more than 99%, and alloying constituents of the metal alloys may be at least 0.01 wt. %. The material may be any one of following semiconductor materials: Si, Ge, GaAs, InP, InAs, InGaAs, CdS, GaN, InGaN, GaSb and InSb. The material may be any one of following oxide materials: SrTiO₃, LaAlO₃, Y₂O₃, RuO₂, CeO₂, MgO, ZrO₂, SiO₂, Al₂O₃ and yttria-stabilized zirconia (YSZ). The material may be any one of the following superconducting materials: YBa₂Cu₃O_{7-δ} (0<δ<0.5), REZ₂Cu₃O_{7-δ} (RE is a rare earth element, Z is an alkaline rare earth element, 0<δ<0.5), Bi—Sr—Ca—Cu—O, TI—Ba—Ca—Cu—O. The modification of the material may be bulk, external or internal. The surface of the material may be monocrystalline, amorphous or polycrystalline structure. The surface of the material may be polished or unpolished. The material may be a substrate, a transition layer, a superconducting layer preformed in the process of manufacturing the superconducting device, or any combination of them. The particle beam may be plasma, an ion beam, or any one of ion beam fluxes containing charged ions of O₂ and Ar, N₂ and O₂, or H₂ and Ar. The alloying constituents of the metal alloysmay be at least 0.1 wt. %.

In some cases, the method of the invention may further comprise the step of annealing the material bombarded with the particle beam, wherein the annealing temperature may be in the range of 100-1500° C.

This new ion surface modification method can improve surface microstructure, make material surface smooth and obtain the high compactness using ion to bombard the material surface under the proper process condition selected. In the meantime, the formation of desired bulk material structure provides a relatively “perfect” template for growth of subsequent epitaxial film. The advantages of the present invention are simple process, easy operation as well as significant change of the surface smoothness and structure of material.

### BRIEF DESCRIPTION OF THE DRAWINGS

FIG. 1 is a schematic diagram showing the device of surface modification using ion sputtering method to modify the surface of a film;

FIG. 2 is a schematic diagram showing the device of surface modification using plasma sputtering method to modify the surface of a film;

FIG. 3 is schematic cross-sectional view showing a high temperature superconducting film conductor;

FIG. 4 is a typical x-ray θ-2θ diffraction pattern of cold rolled Ni tape, in which θ is Bragg diffraction angle of a crystal face, and Intensity is x-ray diffraction intensity;

FIG. 5 is a typical x-ray θ-2θ diffraction pattern of Ni tape after the ion beam bombardment;

FIG. 6 is a typical x-ray rocking curve of Ni tape after the ion beam bombardment; FIG. 7 is a graph showing a change of full width at half maximum (FWHM) of (200) diffraction peak after Ni tape is bombarded with ion beam along different incidence angles;

FIG. 8(a) shows the surface topography under scanning electron microscope of YBCO film with c-axis orientation prepared with TFA-MOD process;

FIG. 8(b) shows the surface topography under scanning electron microscope of YBCO film subjected to ISM bombardment;

FIG. 8(c) shows the surface topography under scanning electron microscope of YBCO film subjected to ISM bombardment and annealing treatment;

FIG. 9 is XRD patterns of three samples shown in FIG. 8;

FIG. 10 is a resistance-temperature relation graph of the three samples of FIG. 8 obtained with a standard four-probe method;

FIG. 11 is Rutherford backscattering/channel patterns analysis of the three Samples of FIG. 8.

### DETAILED DESCRIPTION OF THE INVENTION

The bulk material structure formed after the particle beam bombardment in the present invention refers to a structure designed for realizing desired superconductivity. The modification layer of actual material may be bulk, external or internal:

The internal defect formed after the particle beam bombardment refers to linear dislocation, point defect and the like which are introduced intentionally to achieve certain superconducting performance, for example, to improve performance of magnetic flux pinning.

### EMBODIMENT 1

Ion surface modification with ion beam bombardment is conducted to a cold rolled Ni substrate.

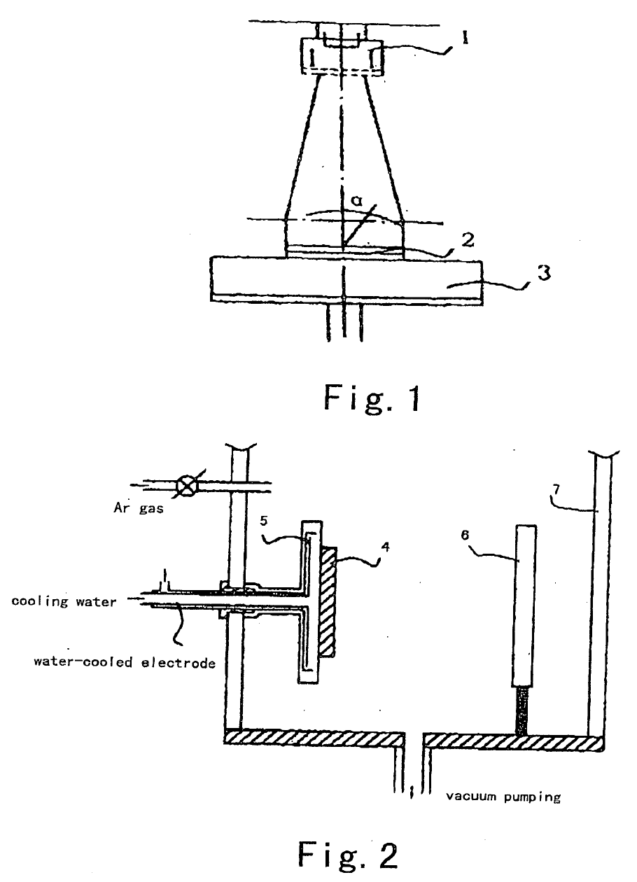

FIG. 1 shows a schematic diagram of reaction chamber structure, which includes a bombardment ion source 1, a sample 2, i.e., a clean rolled Ni substrate, and a sample support 3. The background air pressure of the reaction chamber is 6×10⁻⁴ Pa.

In experiment, the thickness of the cold rolled Ni substrate is 75-120 μm. The substrate is bombarded by Ar⁺ ion beam of 1200 eV, 60 mA, along different incidence angles. As a result, the biaxially textured Ni substrate with (100) preferred orientation is obtained by ion beam bombardment.

FIG. 4 is a typical x-ray θ-2θ diffraction curve of cold rolling Ni tape, and shows random orientation of crystalline grains, including not only a (200) diffraction peak, but also (111) and (220) diffraction peak.

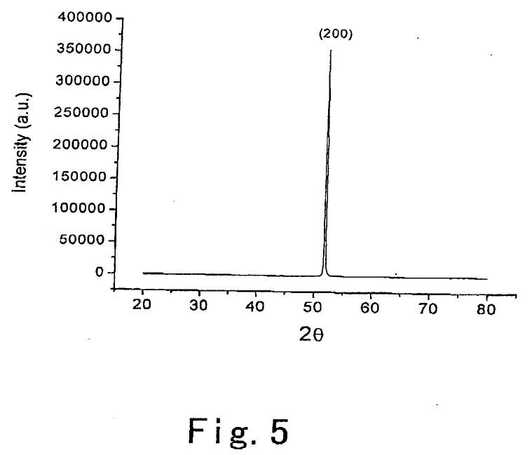

FIG. 5 is an x-ray θ-2θ diffraction curve of Ni tape subjected to the ion beam bombardment along incidence angle of 45°, and shows that the Ni tape has a biaxial texture along (100) preferred orientation.

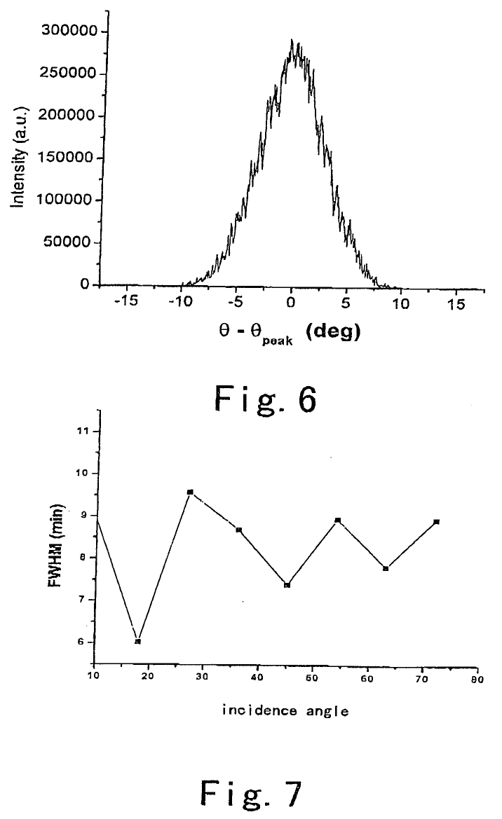

FIG. 6 is an x-ray rocking curve of the sample of FIG. 5, and shows that out-of-plane orientation of Ni sheet is better than 5.9°.

FIG. 7 shows the change in the full width at half maximum (FWHM) of (200) diffraction peak after Ni tape is bombarded with ion beam along different incidence angles, and exhibits the ion beam channeling effect after bombardment.

### EMBODIMENT 2

The ion surface modification is conducted to LaAlO₃ film with plasma sputtering method.

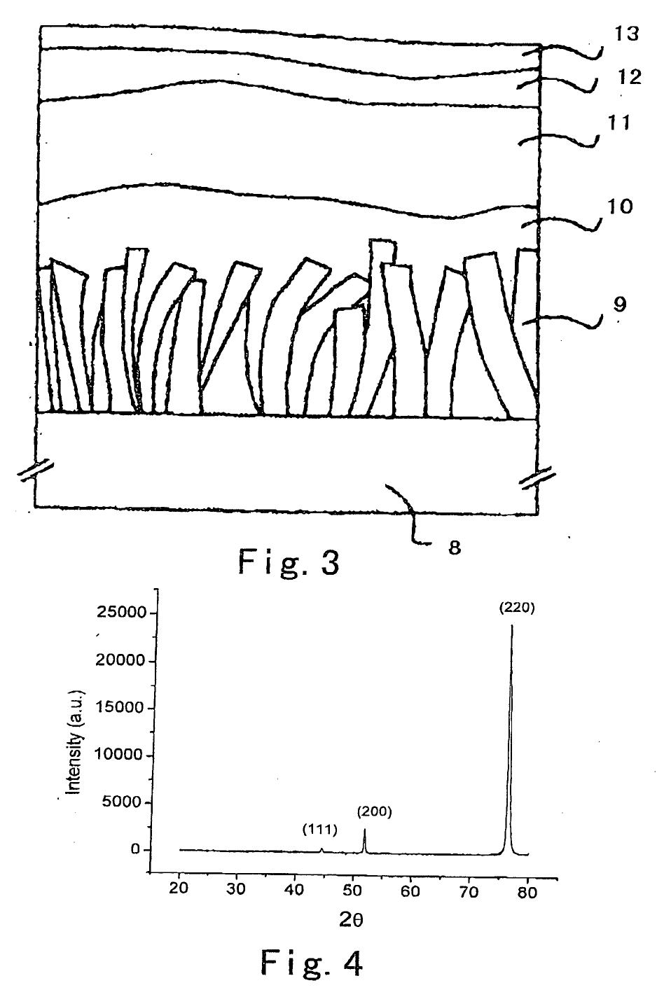

On the clean Ni tape with biaxial texture, a LaAlO₃ buffer layer film with biaxial texture is deposited and obtained through non-vacuum process. The resulting sample is put into the reaction chamber with high vacuum and is subjected to plasma sputtering. The structure of the reaction chamber is shown as FIG. 2, which includes a sample 4, a sample support 5, an electrode 6 and a wall of vacuum chamber 7. The background vacuum of the reaction chamber is 10⁻³-10⁻⁴ Pa. After the voltage of 400-600v is applied to two ends of the electrode, argon gas is filled and glow discharge occurs. The plasma input power is 75 W at 13.65 MHz and glowing time is 1 minute. YBCO film grows on the modified film of LaAlO₃, and then is coated with a passivation layer and a protection layer. The resulting high temperature superconducting device conductor has a cross-section shown in FIG. 3, and comprises a Ni substrate with biaxial texture 8, a LaAlO3 buffer layer 9, an ion-modified surface layer 10, a YBCO film 11, a passivation layer 12 and a protection layer 13. The conductor exhibits superior superconductivity.

### EMBODIMENT 3

Ion surface modification is conducted to YBCO film with ion beam bombardment.

The schematic structure of the reaction chamber is shown as FIG. 1, which includes a bombardment ion source 1, a sample 2, i.e., a clean YBCO film, and a sample support 3. The background air pressure of the reaction chamber is 6×10⁻⁴ Pa. The film is bombarded with Ar⁺ ion beam of 60 mA and 450 eV, along incidence angle of 5-85 degree. Mechanical scanning of ion beam on the platform is realized through synchronous swing of the system. The result shows that the ion beam sputtering improves surface smoothness and compactness of YBCO material, and reduces surface cracks.

Although only one particle beam is mentioned in this embodiment, two or more particle beams may be used, in the practical process, to bombard the material surface at the same time. For instance, in order to attain both the surface smoothness and biaxial texture of the processed material, the appropriate arrangement between beam fluxes can be adopted. In addition, in the practical process, the “Scan” of the object surface is realized through the relative movement between the ion beam flux and the bombarded object. The relative movement may be achieved through the movement of the ion source or the bombarded object.

When the particle beam bombards, the temperature of the whole structure needs to be kept within a certain range. The preferable principle for selecting the temperature range is that the desired structure is not changed due to the temperature effect while the particle beam bombards. The more preferable principle for selecting the temperature range is that structure defects can be eliminated at the selected temperature through thermal annealing while the particle beam bombards.

In addition, the proper environment atmosphere and system pressure should be selected according to the practical demands while particle beam bombards. For instance, when the YBCO film surface is bombarded with ion beam, oxygen atom is sputtered preferably. Thus, the gas with a certain partial pressure of oxygen should be introduced in the system so that oxygen vacancies left by sputtered oxygen atoms are replenished.

The method of the present invention further includes the following step: in some cases, annealing the sample bombarded with particle beam, and the annealing temperature range is in the range of 100-1500° C., if the material surface does not have the desired material texture or superconductivity after being bombarded by the particle beam.

### EMBODIMENT 4

The structure modification is conducted to YBCO surface with ion beam bombardment (ISM) having low energy.

As above stated, a serious problem of using chemistry sol-gel process is that the film has worse microstructure and rough surface, and contains pores, tiny crack defects and large angle grain boundary. In order to resolve this problem, the inventors attempt to modify the microstructure of the YBCO film prepared by the chemistry sol-gel process (TFA-MOD), in order to obtain YBCO superconducting film of high performance that is smooth and flawless, which has significant sense with respect to practical application. The contents of research include effects of ISM and post-annealing treatment on the structure and performance of YBCO film prepared by the TFA-MOD process, as well as the characterization of the structure and electrical performance of the film before and after being modified.

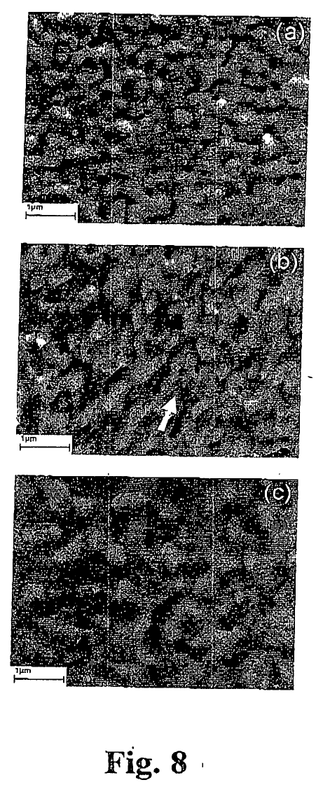

FIG. 8 shows typical surface topographies of different samples under a scanning electronic microscope. FIG. 8(a) shows an initial TFA-MOD film, FIG. 8(b) shows a film subjected to ISM treatment, FIG. 8(c) shows a film subjected to the ISM and post-annealing treatments. As shown in FIG. 8(a), the c-axis oriented YBCO film prepared with the TFA-MOD process contains many pores and tiny cracks, which will affect superconductivity of the film. As shown in FIG. 8(b), after ISM bombardment, pores and tiny cracks disappear; and the topography characteristic of oblique cone exhibits. As shown in FIG. 8(c), after the ISM bombardment and the annealing treatment, the compact, flawless and smooth YBCO surface is obtained. In a sample not subjected to ISM treatment and direct annealing, similar transition of the structure and topography does not occur, which proves that the ISM process has unique function of eliminating micro-defects in the TFA-MOD YBCO film.

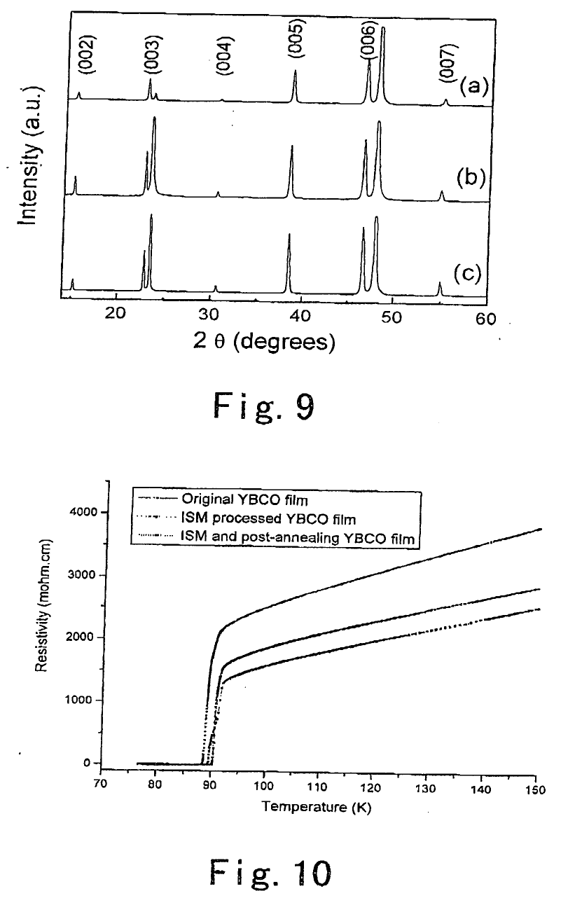

FIG. 9 shows XRD patterns for three samples of FIG. 8, all of which show the YBCO diffraction peaks of (001) direction. This means that the film is highly c-axis oriented, and no impurity phases are produced during the ISM and the subsequent thermal annealing treatment. In addition, the diffraction peak of YBCO is marked in (a), and the unmarked peak is generated from LaAlO₃ substrate.

FIG. 10 shows the resistance-temperature transition graphs for three samples shown in FIG. 8, which is obtained with a standard four-probe method. As shown in FIG. 10, in each case, superconducting transition temperature of the samples (midpoint value) approaches 90K. Particularly, sample A and C exhibit almost similar transition temperature (90.8K), while the transition temperature of sample B is reduced to 89.4K. In addition, sample C exhibits the lowest room temperature resistivity value, and its ratio R(300K)/R(100K)≈3, which is a typical characteristic of YBCO sample with excellent superconductivity. However, two inflexions at its transition location indicate that there are disordered micro domain regions exist in the film.

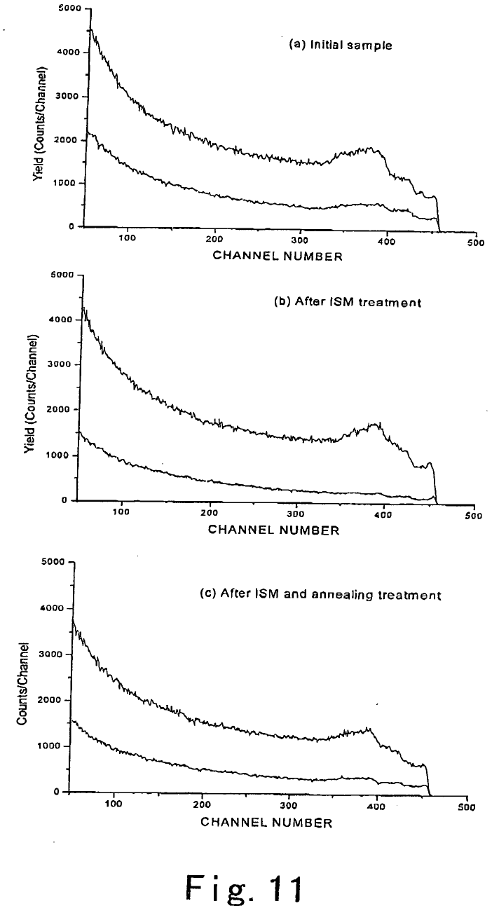

FIG. 11 is a Rutherford backscattering/channeling spectra analysis of three samples in FIG. 8. The analysis testifies that there in no obvious ingredient change in the three samples. It is more important that the value of Xₘᵢₙ is reduced from 37% of sample A to 13% of sample B, which means that the arrangement orderliness inside the film is increased from 63% to 87% by proper ion beam bombardment. However, through the post-annealing treatment, the value of Xₘᵢₙ is increased to 32% again, which means the orderliness of the film is re-reduced. This may be a possible reason why there are two inflexions during the superconducting transition in FIG. 10.

What is claimed is:

1. A method for surface modification in manufacturing high temperature superconducting device, comprising the step of:
bombarding a surface of a preformed material with a particle beam having energy to increase the smoothness of the material surface and change the microstructure or internal defect of the processed material;
wherein the energy of the particle beam is in the range of 5-50000 eV, and the incidence angle of the particle beam is in the range of 5-85 degree.

2. The method according to claim 1, wherein the material is MgO, and the incidence angle of the particle beam is in the range of 35-85 degree.

3. The method according to claim 1, wherein the material is CeO₂, and the incidence angle of the particle beam is in the range of 45-85 degree.

4. The method according to claim 1, wherein the material is a cold rolled Ni substrate, and the incidence angle of the particle beam is in the range of 10-80 degree.

5. The method according to claim 1, wherein the material is YBCO, and the incidence angle of the particle beam is in the range of 5-85 degree.

6. The method according to claim 1, wherein the material is any one of following metal materials: Ni, NiO, Ni alloy, Cu, Cu alloy, Ag, Ag alloy, Fe, Fe alloy, Mg and Mg alloy, purities of the alloy materials are more than 99%, and alloying constituents of the metal alloys are at least 0.01 wt. %.

7. The method according to claim 1, wherein the material is any one of following semiconductor materials: Si, Ge, GaAs, InP, InAs, InGaAs, CdS, GaN, InGaN, GaSb and InSb.

8. The method according to claim 1, wherein the material is any one of following oxide materials: SrTiO₃, LaAlO₃, Y₂O₃, RuO₂, CeO₂, MgO, ZrO₂, SiO₂, Al₂O₃ and yttria-stabilized zirconia (YSZ).

9. The method according to claim 1, wherein the material is any one of the following superconducting materials: YBa₂Cu₃O_{7-δ} (0<θ<0.5), REZ₂Cu₃O_{—δ} (RE is a rare earth element, Z is an alkaline rare earth element, 0<δ<0.5), Bi—Sr—Ca—Cu—O, TI—Ba—Ca—Cu—O.

10. The method according to claim 1, wherein the modification of the material is bulk, external or internal.

11. The method according to claim 1, wherein the surface of the material is monocrystalline, amorphous or polycrystalline structure.

12. The method according to claim 1, wherein the surface of the material is polished or unpolished.

13. The method according to claim 1, wherein the material is a substrate, a transition layer, a superconducting layer preformed in the process of manufacturing the superconducting device, or any combination of them.

14. The method according to claim 1, wherein the particle beam is a plasma, an ion beam, or any one of ion beam fluxes containing charged ions of O₂ and Ar, N₂ and O₂, or H₂ and Ar.

15. The method according to claim 1, further comprising annealing the material bombarded with the particle beam, wherein the annealing temperature is in the range of 100-1500° C.

16. The method according to claim 6, wherein alloying constituents of the metal alloys are at least 0.1 wt. %.

17. A high temperature superconducting device, comprising:
a substrate; and
a high temperature superconducting film formed on the substrate,
wherein the high temperature superconducting film exhibits oblique cone topography characteristic after being bombarded with a particle beam having energy, the energy of the particle beam is in the range of 5-50000 eV, and the incidence angle of the particle beam is in the range of 5-85 degree.

18. The high temperature superconducting device according to claim 17, wherein the high temperature superconducting film is annealed after being bombarded with the particle beam, and the annealing temperature is in the range of 100-1500° C.
